(19) United States
(12) Patent Application Publication
(10) Pub. No.: US 2023/0268891 A1
(43) Pub. Date: Aug. 24, 2023

(54) PROTECTING A CIRCUIT FROM AN INPUT VOLTAGE

(71) Applicant: Microchip Technology Incorporated, Chandler, AZ (US)

(72) Inventors: Henry Liang, Shenzhen (CN); Hongming An, San Diego, CA (US); James Ho, Escondido, CA (US); Congqing Xiong, Shenzhen (CN)

(21) Appl. No.: 17/664,086

(22) Filed: May 19, 2022

(30) Foreign Application Priority Data
Feb. 22, 2022 (CN) 202210160218.8

(51) Int. Cl. H03F 1/56; H03F 1/52

(52) U.S. Cl. CPC H03F 1/56; H03F 1/523; H03F 2200/264; H03F 2200/426

(57) ABSTRACT

This description relates, generally, to protecting a circuit from an input voltage. Various examples include an apparatus including one or more circuits to draw current from, or provide current to, a pair of connectors for an input circuit. The connectors may be for electrical coupling to first and second terminals of a twisted pair. The one or more circuits may be at least partially responsive to positive and negative biasing signals. The apparatus may additionally include an operational amplifier to generate the positive and negative biasing signals. The operational amplifier may include: a first input terminal at least partially responsive to a reference voltage and a second input terminal at least partially responsive to a common-mode voltage of the input circuit. Related systems and methods are also disclosed.

### PRIORITY CLAIM

This application claims the benefit of the filing date of Chinese Patent Application Serial No. 202210160218.8, filed Feb. 22, 2022, for “Protecting a Circuit From an Input Voltage,” the disclosure of which is hereby incorporated herein in its entirety by this reference.

### FIELD

This description relates, generally, to protecting a circuit from an input voltage.

### BACKGROUND

Differential signaling generally describes information transmitted electronically using two different, yet complimentary electrical signals. For example, a single signal may be represented as the signal and its complement, each using its own wire, e.g., in a twisted paired conductor. The differential signal may be affected by interference that is common to both of the complementary signals, i.e., common-mode interference appearing as a common-mode voltage.

### BRIEF DESCRIPTION OF THE DRAWINGS

While this disclosure concludes with claims particularly pointing out and distinctly claiming specific examples, various features and advantages of examples within the scope of this disclosure may be more readily ascertained from the following description when read in conjunction with the accompanying drawings, in which:

FIG. 1 is a hybrid circuit schematic / functional block diagram illustrating an example apparatus according to one or more examples.

FIG. 2 is a hybrid circuit schematic / functional block diagram illustrating an example circuit according to one or more examples.

FIG. 3 illustrates a method according to one or more examples.

FIG. 4 is a functional block diagram depicting an example apparatus according to one or more examples.

FIG. 5 is a functional block diagram depicting an example apparatus according to one or more examples.

FIG. 6 is a functional block diagram depicting an example system according to one or more examples.

### DETAILED DESCRIPTION

In the following detailed description, reference is made to the accompanying drawings, which form a part hereof, and in which are shown, by way of illustration, specific examples in which the present disclosure may be practiced. These examples are described in sufficient detail to enable a person of ordinary skill in the art to practice the present disclosure. However, other examples may be utilized, and structural, material, and process changes may be made without departing from the scope of the disclosure.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example of this disclosure to the specified components, steps, features, functions, or the like.

It will be readily understood that the components of the examples as generally described herein and illustrated in the drawing could be arranged and designed in a wide variety of different configurations. Thus, the following description of various examples is not intended to limit the scope of the present disclosure, but is merely representative of various examples. While the various aspects of the examples may be presented in drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be depicted by block diagram form in order not to obscure the present disclosure in unnecessary detail. Conversely, specific implementations shown and described are only examples and should not be construed as the only way to implement the present disclosure unless specified otherwise herein. Additionally, block definitions and partitioning of logic between various blocks is an example of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art would understand that information and signals may be represented using any of a variety of different technologies and techniques. For example, data, instructions, commands, information, signals, bits, and symbols that may be referenced throughout this description may be represented by voltages, currents, electromagnetic waves, magnetic fields or particles, optical fields or particles, or any combination thereof. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal. A person having ordinary skill in the art would appreciate that this disclosure encompasses communication of quantum information and qubits used to represent quantum information.

The various illustrative logical blocks, modules, and circuits described in connection with the examples disclosed herein may be implemented or performed with a general purpose processor, a special purpose processor, a Digital Signal Processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer is configured to execute computing instructions (e.g., software code) related to examples of the present disclosure.

The examples may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be rearranged. A process may correspond to a method, a thread, a function, a procedure, a subroutine, or a subprogram, without limitation. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

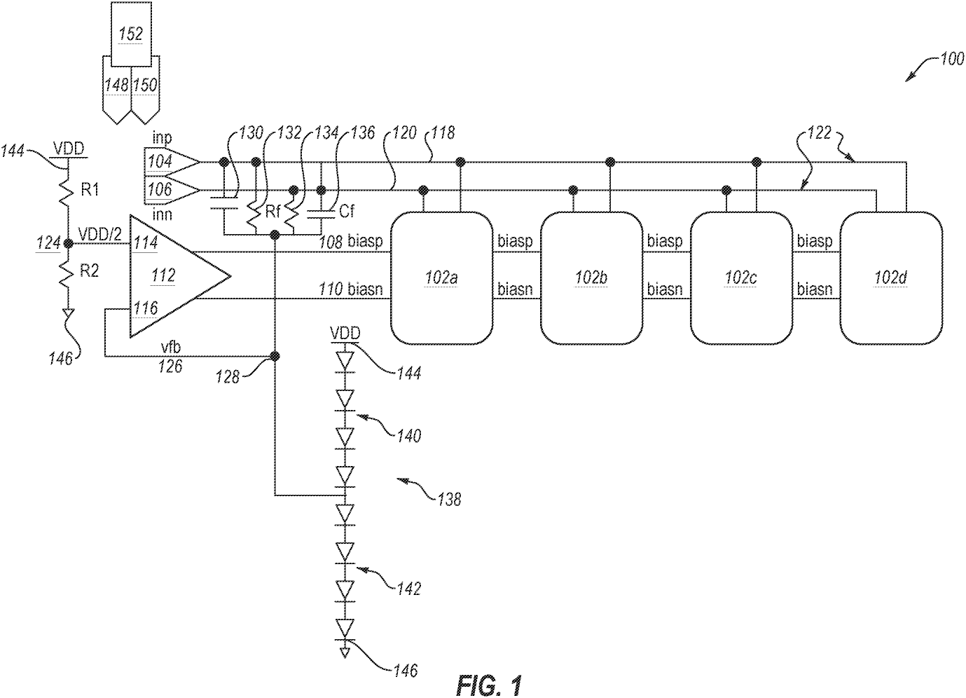

FIG. 1 is a hybrid circuit schematic / functional block diagram illustrating an example apparatus 100 according to one or more examples. Apparatus 100 may alter a differential signal by decreasing a magnitude of voltage common to both of differential signals, i.e., decreasing a common-mode voltage. Apparatus 100 may be electrically coupled to conductors configured to carry a differential signal, e.g., at a transceiver of a signaling device. Apparatus 100 may decrease a magnitude of a common-mode voltage by providing or drawing current. Because the conductors carrying the differential signal may be electrically coupled to a number of devices (e.g., transceivers), decreasing the magnitude of the common-mode voltage at apparatus 100 may benefit all of the number of devices.

Apparatus 100 may include one or more circuits 102 configured to draw current from, or provide current to, a pair of connectors (e.g., connector 104 and connector 106) for an input circuit (not illustrated in FIG. 1). In FIG. 1, for descriptive purposes, apparatus 100 is illustrated including four circuits 102, i.e., circuit 102a, circuit 102b, circuit 102c, and circuit 102d (which may be collectively referred to as circuits 102). Various examples may include any suitable number of circuits 102. The number of circuits 102 included in an apparatus 100 may be a design choice, e.g., based on a level of common-mode voltage to be removed by apparatus 100. For example, each of circuits 102 may draw, or provide, an amount of current (e.g., in the range of hundreds of microamperes, without limitation). Apparatus 100 may be designed to include a number of circuits 102 proportional to an amount of current that may need to be drawn or provided.

Each of circuits 102 may be electrically coupled to both connector 104 and connector 106 through line 118 and line 120 respectively. Connector 104 and connector 106 may be connectors for electrical coupling to terminal 148 and terminal 150 respectively, e.g., of a twisted pair 152. Voltage common to both of line 118 and line 120 may be common-mode voltage 122.

Circuits 102 may draw current from, or provide current to, line 118 and line 120, e.g., to decrease a magnitude of common-mode voltage 122, i.e., decrease a common-mode interference. Apparatus 100 may include a feedback loop to control an amount of current being drawn or provided by circuits 102. For example, circuits 102 may draw current from, or provide current to, line 118 and line 120 at least partially responsive to biasing signal 108 and biasing signal 110 (e.g., a positive biasing signal and a negative biasing signal, respectively).

Operational amplifier 112 may generate the biasing signal 108 and biasing signal 110. Operational amplifier 112 may include input terminal 114 (e.g., a positive input terminal) which may be electrically coupled to a node at which reference voltage 124 is observable. Reference voltage 124 may be selected based on R1 and R2. In some examples, reference voltage 124 may be halfway between a rail voltage 144 (e.g., “VDD”) and ground 146 (e.g., if R1 = R2). Operational amplifier 112 may also include input terminal 116 (e.g., a negative terminal) which may be electrically coupled to node 128 at which feedback voltage (vfb) 126 may be observable. Feedback voltage 126 may be at least partially responsive to common-mode voltage 122 of the apparatus 100. In particular, line 118 and line 120 may be electrically coupled to node 128 through two or more passive elements, e.g., capacitor 130, resistor 132, resistor 134, and capacitor 136. For example, line 118 may be electrically coupled to node 128 through capacitor 130 and resistor 132, and line 120 may be electrically coupled to node 128 through resistor 134 and capacitor 136. Feedback voltage 126 may be between a voltage at line 118 and line 120 based on the ratio of the resistance of the resistor 132 and resistor 134 (and/or the reactance of capacitor 130 and capacitor 136). For example, if resistor 132 has the same resistance as resistor 134, feedback voltage 126 may be halfway between the voltage of line 118 and line 120. Thus, feedback voltage 126 will be related to common-mode voltage 122, e.g., feedback voltage 126 may exhibit voltage common to voltages at line 118 and line 120. Capacitor 130 and capacitor 136 may improve a high-frequency response of apparatus 100.

Operational amplifier 112 may compare a difference between reference voltage 124 and feedback voltage 126 to generate biasing signal 108 and biasing signal 110 based on the difference. For example, when common-mode voltage 122 is higher than reference voltage 124, feedback voltage 126 may also be higher than reference voltage 124. When feedback voltage 126 is higher than reference voltage 124, operational amplifier 112 may increase biasing signal 108 and biasing signal 110. An increase in biasing signal 108 and biasing signal 110 may cause circuits 102 to draw current from line 118 and line 120 to ground (which connection between circuits 102 and ground is not illustrated in FIG. 1), thereby decreasing a magnitude of common-mode voltage 122. As an alternative example, when common-mode voltage 122 is lower than reference voltage 124, feedback voltage 126 may be lower than reference voltage 124. When feedback voltage 126 is lower than reference voltage 124, operational amplifier 112 may decrease biasing signal 108 and biasing signal 110. A decrease in biasing signal 108 and biasing signal 110 may cause circuits 102 to provide current to line 118 and line 120, thereby decreasing the magnitude of common-mode voltage 122 (e.g., where voltages at line 118 and line 120 are negative).

Apparatus 100 may include feedback-voltage protection circuit 138, which may keep feedback voltage 126 within a threshold. For example, feedback-voltage protection circuit 138 may include a first number of diodes 140 arranged between a rail voltage 144 and node 128 and a second number of diodes 142 between node 128 and ground 146. As an example of how feedback-voltage protection circuit 138 may keep feedback voltage 126 within a threshold, if feedback voltage 126 is greater than the collective forward voltages of diodes 142 (e.g., 2.8 volts for four diodes each with a 0.7 volt forward voltage), any excess voltage will be drawn to ground 146. Thus, feedback voltage 126 may be at most the collective forward voltages of diodes 142. As another example, if feedback voltage 126 is less than rail voltage 144 minus the collective forward voltages of diodes 140 (e.g., VDD - 2.8 volts), rail voltage 144 will provide excess voltage. Thus, feedback voltage 126 may be at lowest, rail voltage 144 minus the collective forward voltages of diodes 140. Feedback-voltage protection circuit 138 may, among other things, prevent feedback voltage 126 from damaging operational amplifier 112, e.g., by preventing feedback voltage 126 from exceeding an operational threshold of input terminal 116. In FIG. 1, diodes 140 and diodes 142 are both illustrated as including four diodes each for descriptive purposes. The number of diodes 140 and diodes 142 may be selected based on rail voltage 144 and an operational threshold of input terminal 116.

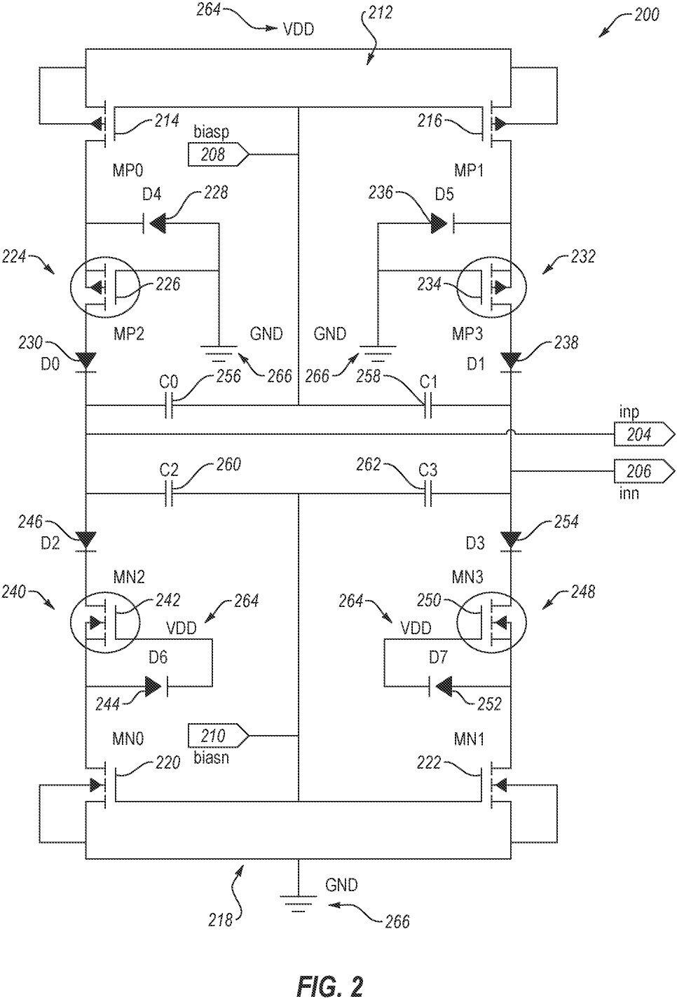

Each of circuits 102 may include a current mirror to draw the current from, or provide the current, to line 118 and line 120 at least partially responsive to biasing signal 108 and biasing signal 110. Further, each of circuits 102 may include a protection circuit to protect a transistor of the current mirror from a voltage of one of connectors. Addition detail regarding an example of circuits 102 is described with regard to FIG. 2.

FIG. 2 is a hybrid circuit schematic / functional block diagram illustrating an example circuit 200 according to one or more examples. Circuit 200 is an example of a circuits 102 of FIG. 1. Circuit 200 may draw current from, or provide current to, input 204 and input 206, e.g., to decrease a magnitude of common-mode voltage at input 204 and input 206.

If circuit 200 were placed in apparatus 100 of FIG. 1 as an instance of circuits 102, input 204 may be electrically coupled to connector 104 of FIG. 1 (e.g., through line 118 of FIG. 1) and input 206 may be electrically coupled to connector 106 of FIG. 1 (e.g., through line 120 of FIG. 1). Further, if circuit 200 were placed in apparatus 100, input 208 may receive biasing signal 108 of FIG. 1 and input 210 may receive biasing signal 110 of FIG. 1.

Circuit 200 may include current mirror 212 to provide current to a pair of inputs (i.e., input 204 and input 206) at least partially responsive to a biasing signal (e.g., as received at input 208 and input 210). Additionally or alternatively, circuit 200 may include current mirror 218 to draw current from input 204 and input 206 at least partially responsive to the biasing signal. For example, when the biasing signal at input 208 and input 210 is low, mirror transistor 214 and mirror transistor 216, denoted respectively MP0, MP1, may allow current to flow from rail voltage 264 (e.g., “VDD”) to input 204 and input 206. When the biasing signal at input 208 and input 210 is high, mirror transistor 220 and mirror transistor 222, denoted respectively MN0, MN1, may allow current from input 204 and input 206 to flow to ground 266.

Circuit 200 may be included in circuits (e.g., apparatus 100) where input 204 and input 206 may exhibit high common-mode voltage (e.g., a common-mode voltage that is higher than rail voltage 264 or lower than ground 266). In some examples, circuit 200 may be included in circuits where input 204 and input 206 exhibit voltages up to about 40 volts and as low as about -40 volts.

To allow circuit 200 to operate with a high common-mode voltage at input 204 and input 206, circuit 200 may include protection circuits to protect mirror transistor 214, mirror transistor 216, mirror transistor 220, and mirror transistor 222 from being affected by the high voltages of input 204 and input 206. For example, circuit 200 may include protection circuit 224 (e.g., a “first protection circuit 224”) to protect mirror transistor 214 (e.g., a “first transistor 214”) of current mirror 212 (e.g., a “first current mirror 212”) from excessive voltage at input 204. Circuit 200 may also include protection circuit 232 (e.g., a “second protection circuit 232”) to protect mirror transistor 216 (e.g., a “second transistor 216”) of current mirror 212 from excessive voltage at input 206. Circuit 200 may also include protection circuit 240 (e.g., a “third protection circuit 240”) to protect mirror transistor 220 (e.g., a “third transistor 220”) of current mirror 218 (e.g., a “second current mirror 218”) from excessive voltage at input 204. Circuit 200 may also include protection circuit 248 (e.g., a “fourth protection circuit 248”) to protect mirror transistor 222 (e.g., a “fourth transistor 222”) of current mirror 218 from excessive voltage at input 206.

Each of protection circuit 224, protection circuit 232, protection circuit 240, and protection circuit 248 may include a respective high-voltage-capable diode, i.e., protection circuit 224 may include HV diode 230 (denoted D0), protection circuit 232 may include HV diode 238 (denoted D1), protection circuit 240 may include HV diode 246 (denoted D2), and protection circuit 248 may include HV diode 254 (denoted D3). Each of HV diode 230, HV diode 238, HV diode 246, and HV diode 254 may be capable of withstanding a high reverse voltage without breaking down or allowing a current to flow. For example, each of HV diode 230, HV diode 238, HV diode 246, and HV diode 254 may be capable of not breaking down or allowing current to flow despite a reverse voltage of up to 80 volts, as a non-limiting example.

Thus, for example, if input 204 exhibits a voltage higher than rail voltage 264, HV diode 230 may protect HV transistor 226 and/or mirror transistor 214 by preventing the body-junction breakdown of HV transistor 226 and/or mirror transistor 214 and preventing unintended current to flow from input 204 to HV transistor 226 and/or mirror transistor 214. Similarly, if input 206 exhibits a voltage higher than rail voltage 264, HV diode 238 may protect HV transistor 234 and/or mirror transistor 216 by preventing the body-junction breakdown of HV transistor 234 and/or mirror transistor 216 and preventing unintended current to flow from input 206 to HV transistor 234 and/or mirror transistor 216. Similarly, if input 204 exhibits a voltage lower than ground 266, HV diode 246 may protect HV transistor 242 and/or mirror transistor 220 by preventing the body-junction breakdown of HV transistor 242 and/or mirror transistor 220 and preventing unintended current to flow from HV transistor 242 and/or mirror transistor 220 to input 204. Similarly, if input 206 exhibits a voltage lower than ground 266, HV diode 254 may protect HV transistor 250 and/or mirror transistor 222 by preventing the body-junction breakdown of HV transistor 250 and/or mirror transistor 220 and preventing unintended current to flow from HV transistor 250 and/or mirror transistor 220 to input 204.

Further, each of protection circuit 224, protection circuit 232, protection circuit 240, and protection circuit 248 may include a high-voltage capable transistor, e.g., a laterally-diffused (LD) metal-oxide semiconductor (MOS) field-effect transistor (FET). For example, protection circuit 224 may include HV transistor 226 (which may be an LD positive-channel MOS (LD-PMOS) transistor - denoted MP2), protection circuit 232 may include HV transistor 234 (which may be an LD-PMOS transistor - denoted MP3), protection circuit 240 may include HV transistor 242 (which may be an LD negative-channel MOS (LD-NMOS) transistor - denoted MN2), and protection circuit 248 may include HV transistor 250 (which may be an LD-NMOS transistor -denoted MN2). Each of HV transistor 226, HV transistor 234, HV transistor 242, and HV transistor 250 may be capable of withstanding a high drain-to-source voltage (and/or source-to-drain voltage) without breaking down or allowing a current to flow. For example, each of HV transistor 226, HV transistor 234, HV transistor 242, and HV transistor 250 may be capable of not breaking down or allowing current to flow despite a drain-to-source voltage (or source-to-drain voltage) of up to 60 volts, as a non-limiting example.

For example, when input 204 exhibits a voltage lower than ground 266, HV transistor 226, whose gate is connected to ground 266, may clamp the drain voltage of mirror transistor 214 to ground 266 plus a threshold voltage of HV transistor 226 thereby preventing a source-to-drain voltage of mirror transistor 214 from exceeding a safe-operation region. Further, HV transistor 226 may be capable of withstanding a source-to-drain of up to 60 volts, as a non-limiting example. Thus, if input 204 exhibits a voltage of 40 volts, as a non-limiting example, HV transistor 226 may continue to operate without breaking down. Similarly, when input 206 exhibits a voltage lower than ground 266, HV transistor 234, whose gate is connected to ground 266, may clamp the drain voltage of mirror transistor 216 to ground 266 plus a threshold voltage of HV transistor 234 thereby preventing a source-to-drain voltage of mirror transistor 216 from exceeding a safe-operation region. Further, HV transistor 234 may be capable of withstanding a source-to-drain of up to 60 volts, as a non-limiting example. Thus, if input 206 exhibits a voltage of 40 volts, as a non-limiting example, HV transistor 226 may continue to operate without breaking down. Similarly, when input 204 exhibits a voltage higher than rail voltage 264, HV transistor 242, whose gate is connected to rail voltage 264, may clamp the drain voltage of mirror transistor 220 to rail voltage 264 minus a threshold voltage of HV transistor 242 thereby preventing a drain-to-source voltage of mirror transistor 220 from exceeding a safe-operation region. Further, HV transistor 242 may be capable of withstanding a drain-to-source of up to 60 volts, as a non-limiting example. Thus, if input 204 exhibits a voltage of 40 volts, as a non-limiting example, HV transistor 242 may continue to operate without breaking down. Similarly, when input 206 exhibits a voltage higher than rail voltage 264, HV transistor 250, whose gate is connected to rail voltage 264, may clamp the drain voltage of mirror transistor 222 to rail voltage 264 minus a threshold voltage of HV transistor 250 thereby preventing a drain-to-source voltage of mirror transistor 222 from exceeding a safe-operation region. Further, HV transistor 250 may be capable of withstanding a drain-to-source of up to 60 volts, as a non-limiting example. Thus, if input 206 exhibits a voltage of 40 volts, as a non-limiting example, HV transistor 250 may continue to operate without breaking down.

Further, each of protection circuit 224, protection circuit 232, protection circuit 240, and protection circuit 248 may include a diode between a respective mirror transistor of a respective current mirror and both a gate of a respective HV transistor of the respective protection circuit and a rail voltage or ground.

For example, protection circuit 224 may include diode 228, denoted D4, facing forward (e.g., allowing current to flow) between ground 266 and a common connection of a source of HV transistor 226 and a drain of mirror transistor 214 of current mirror 212. Diode 228 may prevent current to flow from current mirror 212 (and from the source of HV transistor 226) to ground 266. Diode 228 may function during power-down to prevent the drain of mirror transistor 214 from dropping below ground 266 minus 0.7 volts. Similarly, protection circuit 232 may include diode 236, denoted D5, facing forward between ground 266 and a common connection of a source of HV transistor 234 and a drain of mirror transistor 216 of current mirror 212. Diode 236 may prevent current to flow from current mirror 212 (and from the source of HV transistor 234) to ground 266. Diode 236 may function during power-down to prevent the drain of mirror transistor 216 from dropping below ground 266 minus 0.7 volts. Similarly, protection circuit 240 may include diode 244, denoted D6, facing forward between a common connection of a drain of mirror transistor 220 of current mirror 218 and a source of HV transistor 242 and rail voltage 264. Diode 244 may prevent current to flow from rail voltage 264 to current mirror 218 (and to the source of HV transistor 242). Diode 244 may function during power-down to prevent the drain of mirror transistor 220 from rising above rail voltage 264 +0.7 volts. Similarly, protection circuit 248 may include diode 252, denoted D7, facing forward between a common connection of a drain of mirror transistor 222 of current mirror 218 and a source of HV transistor 250 and rail voltage 264. Diode 252 may prevent current to flow from rail voltage 264 to current mirror 218 (and to the source of HV transistor 250). Diode 252 may function during power-down to prevent the drain of mirror transistor 222 from rising above rail voltage 264 +0.7 volts.

Circuit 200 may also include capacitor 256, denoted C0, electrically coupled between input 204 and input 208, capacitor 258, denoted C1, electrically coupled between input 206 and input 208, capacitor 260, denoted C2, electrically coupled between input 204 and input 210, and capacitor 262, denoted C3, electrically coupled between input 206 and input 210. Capacitor 256, capacitor 258, capacitor 260, and capacitor 262 may provide high-frequency compensation. For example, if a frequency of input 204 and input 206 is higher than an operational amplifier’s bandwidth (e.g., input terminal 114 of FIG. 1), capacitor 256, capacitor 258, capacitor 260, and capacitor 262 may feedback common-mode voltage directly to input 208 and input 210 and control input impedance through mirror transistor 216, current mirror 218, mirror transistor 220 and mirror transistor 222. Additionally, capacitor 256 may be viewed as between input 204 and a gate of mirror transistor 214 and/or a gate of mirror transistor 216. Similarly, capacitor 258 may be viewed as between input 206 and a gate of mirror transistor 214 and/or a gate of mirror transistor 216. Similarly, capacitor 260 may be viewed as between input 204 and a gate of mirror transistor 220 and/or a gate of mirror transistor 222. Similarly, capacitor 262 may be viewed as between input 206 and a gate of mirror transistor 220 and/or a gate of mirror transistor 222.

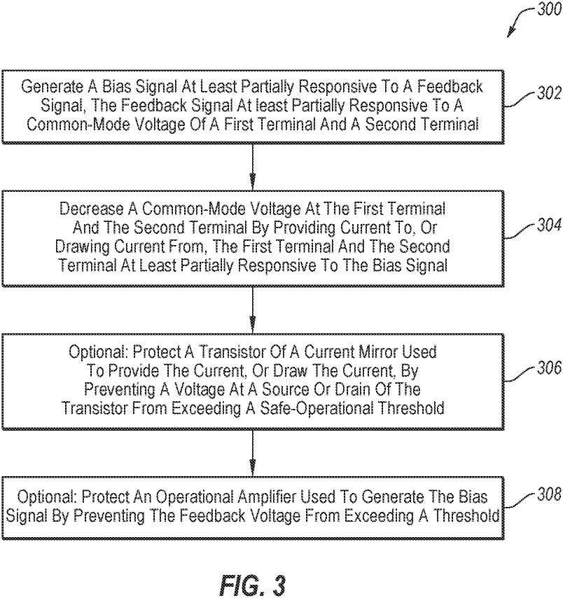

FIG. 3 is a flowchart of an example method 300, in accordance with various examples of the disclosure. At least a portion of method 300 may be performed, in some examples, by a device or system, such as apparatus 100 of FIG. 1 or another device or system. Although illustrated as discrete blocks, various blocks may be divided into additional blocks, combined into fewer blocks, or eliminated, depending on the desired implementation.

At block 302, a bias signal may be generated at least partially responsive to a feedback signal. The feedback signal may be at least partially responsive to a common-mode voltage of a first terminal and a second terminal. For example, biasing signal 108 of FIG. 1 and biasing signal 110 of FIG. 1 may be generated responsive to feedback voltage 126 of FIG. 1. Feedback voltage 126 may be at least partially responsive to common-mode voltage 122 of connector 104 of FIG. 1 and connector 106 of FIG. 1.

At block 304, a common-mode voltage may be decreased at the first terminal and the second terminal by a current provided to, or drawn current from, the first terminal and the second terminal at least partially responsive to the bias signal. For example, circuits 102 of FIG. 1 may provide current to, or draw current from, connector 104 and connector 106 at least partially responsive to biasing signal 108 and biasing signal 110.

At block 306, which may be optional, a transistor of a current mirror used to provide the current, or draw the current, may be protected by preventing a voltage at a source or drain of the transistor from exceeding a safe-operational threshold. For example, mirror transistor 214 of FIG. 2 of current mirror 212 of FIG. 2 may be protected by protection circuit 224 of FIG. 2, which may prevent a voltage at source or drain of mirror transistor 214 from exceeding a safe operational threshold of mirror transistor 214

At block 308, which may be optional, an operational amplifier used to generate the bias signal may be protected by preventing the feedback voltage from exceeding a threshold. For example, operational amplifier 112 of FIG. 1 may be protected by feedback-voltage protection circuit 138 of FIG. 1 preventing feedback voltage 126 from exceeding a safe operational threshold of operational amplifier 112.

Modifications, additions, or omissions may be made to method 300 without departing from the scope of the present disclosure. For example, the operations of method 300 may be implemented in differing order. Furthermore, the outlined operations and actions are only provided as examples, and some of the operations and actions may be optional, combined into fewer operations and actions, or expanded into additional operations and actions without detracting from the essence of the disclosed example.

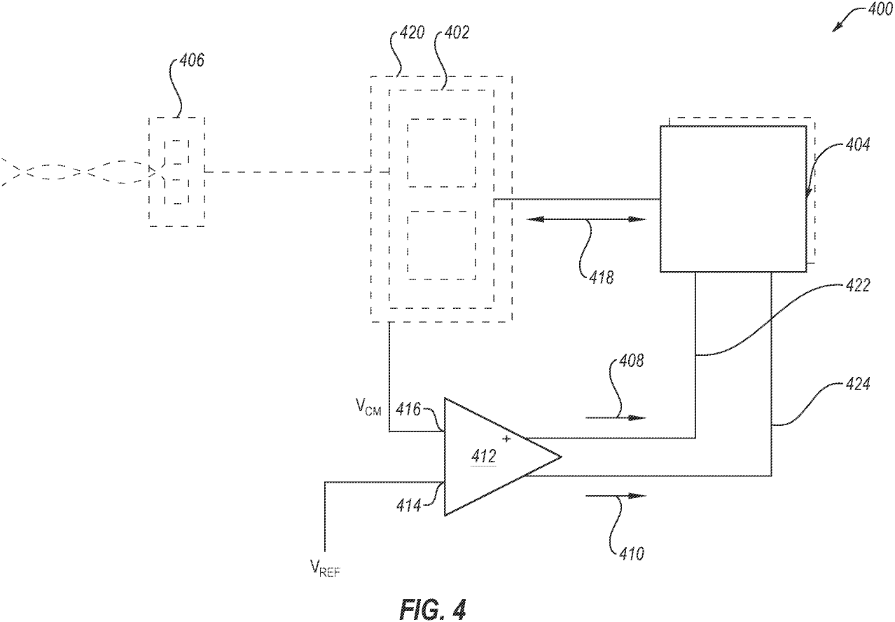

FIG. 4 is a functional block diagram depicting an example apparatus 400 according to one or more examples. Apparatus 400 may alter a differential signal by decreasing a magnitude of voltage common to both differential signals, i.e., a common-mode voltage.

Apparatus 400 may include an input circuit 420 (which input circuit 420 may include a pair of connectors 402), one or more circuits 404 (each of one or more circuits 404 may include a first input 422, and a second input 424 respectively), and an operational amplifier 412 (which operational amplifier 412 may include a first input terminal 414 and a second input terminal 416). Additionally illustrated in FIG. 1 are terminals of a twisted pair 406, a positive biasing signal 408 (which positive biasing signal 408 may be a signal between an output (e.g., a positive output) of operational amplifier 412 and first input 422), a negative biasing signal 410 (which negative biasing signal 410 may be a signal between another output (e.g., a negative output) of operational amplifier 412 and second input 424), a first current 418 (which current 418 may be a current between pair of connectors 402 and one or more circuits 404).

Terminals of a twisted pair 406, pair of connectors 402, input circuit 420 and more than one of one or more circuits 404 are optional. The optionality of pair of connectors 402, terminals of a twisted pair 406, input circuit 420 and more than one of one or more circuits 404 is depicted in FIG. 4 using dashed lines.

In the non-limiting example depicted by FIG. 4, apparatus 400 may include one or more circuits 404, which one or more circuits 404 may draw current 418 from, or provide current 418 to, pair of connectors 402 of input circuit 420. Pair of connectors 402 may be for electrical coupling to first and second terminals of a twisted pair 406. Respective first input 422 and second input 424 of one or more circuits 404 may be at least partially responsive to positive biasing signal 408 and negative biasing signal 410.

Further, apparatus 400 may include operational amplifier 412 to generate positive biasing signal 408 and negative biasing signal 410. Operational amplifier 412 may include first input terminal 414 (which first input terminal 414 may be at least partially responsive to a reference voltage (V_{REF})) and second input terminal 416 (which second input terminal 416 may be at least partially responsive to a common-mode voltage of the input circuit (V_{CM})).

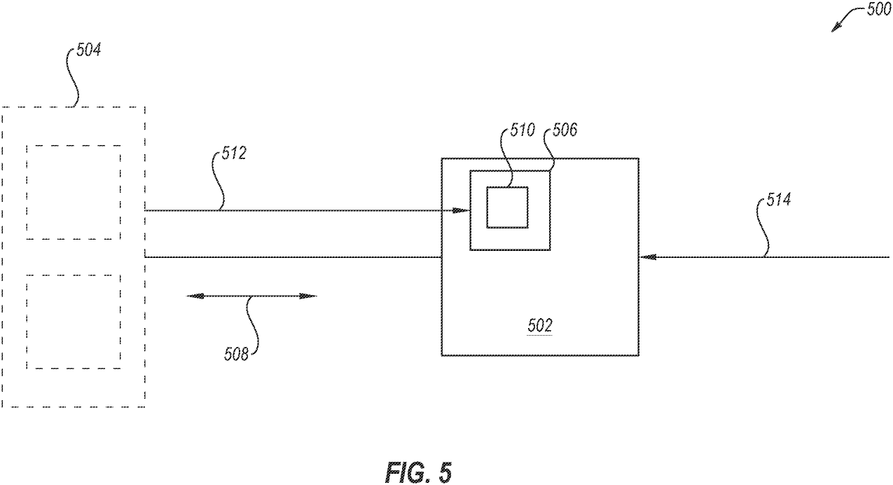

FIG. 5 is a functional block diagram depicting an example apparatus 500 according to one or more examples. Apparatus 500 may draw a current 508 from, or provide current 508 to a pair of inputs 504.

In the non-limiting example depicted by FIG. 5, apparatus 500 may include a current mirror 502 (which current mirror 502 may include a transistor 510) and a protection circuit 506. Additionally pair of inputs 504 are depicted in FIG. 5; pair of inputs 504 are optional. The optionality of pair of inputs 504 is depicted in FIG. 5 using dashed lines. Additionally depicted in FIG. 5 are a voltage 512 (which may be a voltage at, or of, pair of inputs 504) and a biasing signal 514 (which may be received by current mirror 502).

Current mirror 502 may draw current 508 from, or provide current 508 to, pair of inputs 504 at least partially responsive to biasing signal 514. Protection circuit 506 may protect transistor 510 of current mirror 502 from voltage 512 of one or more of pair of inputs 504.

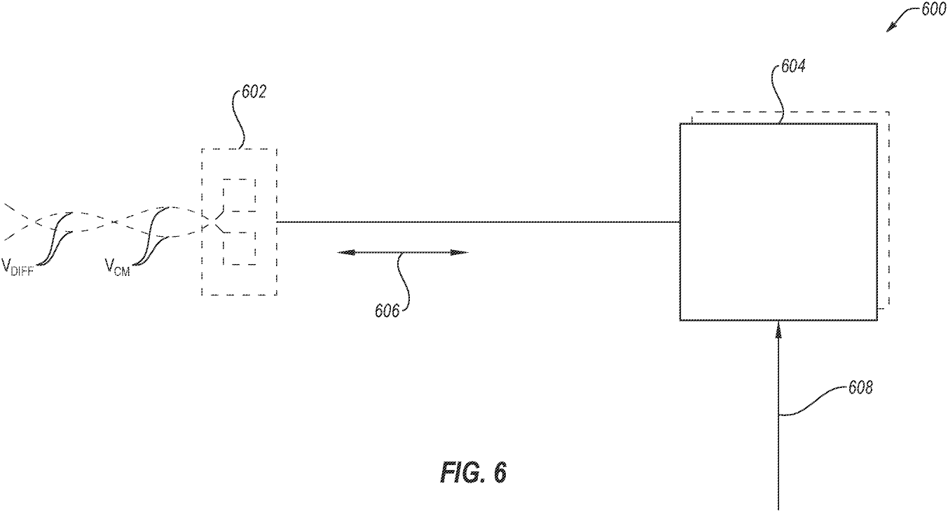

FIG. 6 is a functional block diagram depicting an example system 600 according to one or more examples. System 600 may decrease a common-mode voltage (V_{CM}) at first and second connectors 602 (which may be for electrically coupling to respective first and second terminals of a twisted pair). System 600 may further maintain a differential signal (V_{DIFF}) at the first and second connectors (which may be for electrically coupling to the respective first and second terminals of the twisted pair).

In the non-limiting example depicted by FIG. 6, system 600 may include first and second connectors 602 for electrically coupling with respective first and second terminals of a twisted pair and one or more circuits 604. Additionally depicted in FIG. 6 are a current 606 (which current 606 may be a current between first and second connectors 602 of a twisted pair and one or more circuits 604) and positive and negative biasing signals 608 (which positive and negative biasing signals 608 may be received by one or more circuits 604).

One or more circuits 604 may be electrically coupled to the first and second connectors 602 (which may electrically couple to respective first and second terminals of a twisted pair) to decrease a common-mode voltage (V_{CM}) at the first and second connectors 602 (which may decrease common-mode voltage of the twisted pair). Further, the one or more circuits 604 may maintain a differential signal (V_{DIFF}) at the first and second connectors 602 (which may maintain the differential signal of the twisted pair) by selectively drawing current 606 from, or providing current 606 to, the first and second connectors 602 at least partially responsive to positive and negative biasing signals 608.

As used in the present disclosure, the terms “module” or “component” may refer to specific hardware implementations configured to perform the actions of the module or component and/or software objects or software routines that may be stored on and/or executed by general purpose hardware (e.g., computer-readable media, processing devices, without limitation) of the computing system. In various examples, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations or a combination of software and specific hardware implementations are also possible and contemplated.

As used in the present disclosure, the term “combination” with reference to a plurality of elements may include a combination of all the elements or any of various different sub-combinations of some of the elements. For example, the phrase “A, B, C, D, or combinations thereof” may refer to any one of A, B, C, or D; the combination of each of A, B, C, and D; and any sub-combination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” without limitation).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, without limitation” or “one or more of A, B, and C, without limitation” is used, in general such a construction is intended to include A alone, B alone, C alone, A and B together, A and C together, B and C together, or A, B, and C together, without limitation.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additional non-limiting examples of the disclosure may include:

Example 1: An apparatus, comprising: one or more circuits to draw current from, or provide current to, a pair of connectors for an input circuit, the connectors for electrical coupling to first and second terminals of a twisted pair, respective first and second inputs of the one or more circuits at least partially responsive to positive and negative biasing signals; and an operational amplifier to generate the positive and negative biasing signals, the operational amplifier comprising: a first input terminal at least partially responsive to a reference voltage; and a second input terminal at least partially responsive to a common-mode voltage of the input circuit.

Example 2: The apparatus according to Example 1, wherein the second input terminal of the operational amplifier is at least partially responsive to a feedback voltage and the feedback voltage is observable at a node electrically connected to both of the pair of connectors.

Example 3: The apparatus according to any of Examples 1 and 2, comprising a feedback-voltage protection circuit to cause a feedback voltage to be within a threshold.

Example 4: The apparatus according to any of Examples 1 through 3, wherein the feedback-voltage protection circuit comprises a first number of diodes arranged between a rail voltage and a node at the feedback voltage and a second number of diodes between the node at the feedback voltage and ground.

Example 5: The apparatus according to any of Examples 1 through 4, wherein each of the one or more circuits comprise: a current mirror to draw the current from, or provide the current to, the pair of connectors at least partially responsive to the positive and negative biasing signals.

Example 6: The apparatus according to any of Examples 1 through 5, wherein each of the one or more circuits comprise: a protection circuit to protect a transistor of the current mirror from a voltage of one of the pair of connectors.

Example 7: An apparatus comprising: a current mirror to draw current from, or provide current to, a pair of inputs at least partially responsive to a biasing signal; and a protection circuit to protect a transistor of the current mirror from a voltage of one of the pair of inputs.

Example 8: The apparatus according to Example 7, wherein the current mirror comprises a first current mirror to draw current from the pair of inputs, and wherein the protection circuit comprises a first protection circuit to protect a first transistor of the first current mirror from a first voltage of the one of the pair of inputs, the apparatus comprising: a second protection circuit to protect a second transistor of the first current mirror from a second voltage of the other of the pair of inputs; a second current mirror to provide current to the pair of inputs; a third protection circuit to protect a third transistor of the second current mirror from a third voltage of the one of the pair of inputs; and a fourth protection circuit to protect a fourth transistor of the second current mirror from a fourth voltage of the other of the pair of inputs.

Example 9: The apparatus according to any of Examples 7 and 8, wherein the protection circuit comprises a high-voltage-capable diode between the one of the pair of inputs and the transistor of the current mirror.

Example 10: The apparatus according to any of Examples 7 through 9, wherein the current mirror is to draw current from the pair of inputs and the high-voltage-capable diode is to prevent a flow of current from the current mirror into the one of the pair of inputs.

Example 11: The apparatus according to any of Examples 7 through 10, wherein the current mirror is to provide current to the pair of inputs and the high-voltage-capable diode is to prevent a flow of current from the one of the pair of inputs into the current mirror.

Example 12: The apparatus according to any of Examples 7 through 11, wherein the protection circuit comprises a high-voltage-capable transistor electrically connected between the one of the pair of inputs and the transistor of the current mirror.

Example 13: The apparatus according to any of Examples 7 through 12, wherein the high-voltage-capable transistor is to withstand a voltage difference between a source or drain of the high-voltage-capable transistor that is electrically connected to the one of the pair of inputs and the other of the source or drain of the high-voltage-capable transistor that is electrically connected to the transistor of the current mirror.

Example 14: The apparatus according to any of Examples 7 through 13, wherein the current mirror is to draw current from the pair of inputs, wherein a gate of the high-voltage-capable transistor is electrically coupled to a voltage rail, and wherein a diode is electrically connected between the gate of the high-voltage-capable transistor and the other of the source of the high-voltage-capable transistor.

Example 15: The apparatus according to any of Examples 7 through 14, wherein the diode is to prevent a flow of current from the voltage rail to the source of the high-voltage-capable transistor.

Example 16: The apparatus according to any of Examples 7 through 15, wherein the current mirror is to provide current to the pair of inputs, wherein a gate of the high-voltage-capable transistor is electrically coupled to a ground, and wherein a diode is electrically connected between the gate and the source of the high-voltage-capable transistor.

Example 17: The apparatus according to any of Examples 7 through 16, wherein the diode is to prevent a flow of current from the source of the high-voltage-capable transistor to the ground electrically coupled to the gate of the high-voltage-capable transistor.

Example 18: The apparatus according to any of Examples 7 through 17, comprising a capacitor between one of the pair of inputs and a gate of the transistor of the current mirror.

Example 19: A system, comprising: first and second connectors for electrical coupling to respective first and second terminals of a twisted pair; and one or more circuits coupled to the first and second connectors to decrease a common-mode voltage at the first and second connectors and maintain a differential signal at the first and second connectors by selectively drawing current from, or providing current to, the first and second connectors at least partially responsive to positive and negative biasing signals.

Example 20: The system according to Example 19, further comprising: an operational amplifier to generate the positive and negative biasing signals, the operational amplifier comprising: a first input terminal at least partially responsive to a reference voltage; and a second input terminal at least partially responsive to the common-mode voltage.

Example 21: A method comprising: generating a bias signal at least partially responsive to a feedback signal, the feedback signal at least partially responsive to a common-mode voltage of a first terminal and a second terminal; and decreasing a common-mode voltage at the first terminal and the second terminal by providing current to, or drawing current from, the first terminal and the second terminal at least partially responsive to the bias signal.

Example 22: The method according to Example 21, comprising: protecting a transistor of a current mirror used to provide the current, or draw the current, by preventing a voltage at a source or drain of the transistor from exceeding a safe-operational threshold.

Example 23: The method according to Examples 21 and 22, comprising: protecting an operational amplifier used to generate the bias signal by preventing the feedback signal from exceeding a threshold.

While the present disclosure has been described herein with respect to certain illustrated examples, those of ordinary skill in the art will recognize and appreciate that the present invention is not so limited. Rather, many additions, deletions, and modifications to the illustrated and described examples may be made without departing from the scope of the invention as hereinafter claimed along with their legal equivalents. In addition, features from one example may be combined with features of another example while still being encompassed within the scope of the invention as contemplated by the inventor.

What is claimed is:

1. An apparatus, comprising:
one or more circuits to draw current from, or provide current to, a pair of connectors for an input circuit, the pair of connectors for electrical coupling to first and second terminals of a twisted pair, respective first and second inputs of the one or more circuits at least partially responsive to positive and negative biasing signals; and
an operational amplifier to generate the positive and negative biasing signals, the operational amplifier comprising:
a first input terminal at least partially responsive to a reference voltage; and
a second input terminal at least partially responsive to a common-mode voltage of the input circuit.

2. The apparatus of claim 1, wherein the second input terminal of the operational amplifier is at least partially responsive to a feedback voltage and the feedback voltage is observable at a node electrically connected to both of the pair of connectors.

3. The apparatus of claim 1, comprising a feedback-voltage protection circuit to cause a feedback voltage to be within a threshold.

4. The apparatus of claim 3, wherein the feedback-voltage protection circuit comprises a first number of diodes arranged between a rail voltage and a node at the feedback voltage and a second number of diodes between the node at the feedback voltage and ground.

5. The apparatus of claim 1, wherein each of the one or more circuits comprise: a current mirror to draw the current from, or provide the current to, the pair of connectors at least partially responsive to the positive and negative biasing signals.

6. The apparatus of claim 5, wherein each of the one or more circuits comprise: a protection circuit to protect a transistor of the current mirror from a voltage of one of the pair of connectors.

7. An apparatus comprising:
a current mirror to draw current from, or provide current to, a pair of inputs at least partially responsive to a biasing signal; and
a protection circuit to protect a transistor of the current mirror from a voltage of one of the pair of inputs.

8. The apparatus of claim 7, wherein the current mirror comprises a first current mirror to draw current from the pair of inputs, and wherein the protection circuit comprises a first protection circuit to protect a first transistor of the first current mirror from a first voltage of the one of the pair of inputs, the apparatus comprising:
a second protection circuit to protect a second transistor of the first current mirror from a second voltage of the other of the pair of inputs;
a second current mirror to provide current to the pair of inputs;
a third protection circuit to protect a third transistor of the second current mirror from a third voltage of the one of the pair of inputs; and
a fourth protection circuit to protect a fourth transistor of the second current mirror from a fourth voltage of the other of the pair of inputs.

9. The apparatus of claim 7, wherein the protection circuit comprises a high-voltage-capable diode between the one of the pair of inputs and the transistor of the current mirror.

10. The apparatus of claim 9, wherein the current mirror is to draw current from the pair of inputs and the high-voltage-capable diode is to prevent a flow of current from the current mirror into the one of the pair of inputs.

11. The apparatus of claim 9, wherein the current mirror is to provide current to the pair of inputs and the high-voltage-capable diode is to prevent a flow of current from the one of the pair of inputs into the current mirror.

12. The apparatus of claim 7, wherein the protection circuit comprises a high-voltage-capable transistor electrically connected between the one of the pair of inputs and the transistor of the current mirror.

13. The apparatus of claim 12, wherein the high-voltage-capable transistor is to withstand a voltage difference between a source or drain of the high-voltage-capable transistor that is electrically connected to the one of the pair of inputs and the other of the source or drain of the high-voltage-capable transistor that is electrically connected to the transistor of the current mirror.

14. The apparatus of claim 13, wherein the current mirror is to draw current from the pair of inputs, wherein a gate of the high-voltage-capable transistor is electrically coupled to a voltage rail, and wherein a diode is electrically connected between the gate of the high-voltage-capable transistor and the other of the source of the high-voltage-capable transistor.

15. The apparatus of claim 14, wherein the diode is to prevent a flow of current from the voltage rail to the source of the high-voltage-capable transistor.

16. The apparatus of claim 13, wherein the current mirror is to provide current to the pair of inputs, wherein a gate of the high-voltage-capable transistor is electrically coupled to a ground, and wherein a diode is electrically connected between the gate and the source of the high-voltage-capable transistor.

17. The apparatus of claim 16, wherein the diode is to prevent a flow of current from the source of the high-voltage-capable transistor to the ground electrically coupled to the gate of the high-voltage-capable transistor.

18. The apparatus of claim 7, comprising a capacitor between one of the pair of inputs and a gate of the transistor of the current mirror.

19. A system, comprising:
first and second connectors for electrical coupling to respective first and second terminals of a twisted pair; and
one or more circuits coupled to the first and second connectors to decrease a common-mode voltage at the first and second connectors and maintain a differential signal at the first and second connectors by selectively drawing current from, or providing current to, the first and second connectors at least partially responsive to positive and negative biasing signals.

20. The system of claim 19, further comprising:
an operational amplifier to generate the positive and negative biasing signals, the operational amplifier comprising:
a first input terminal at least partially responsive to a reference voltage; and
a second input terminal at least partially responsive to the common-mode voltage.

21. A method comprising:
generating a bias signal at least partially responsive to a feedback signal, the feedback signal at least partially responsive to a common-mode voltage of a first terminal and a second terminal; and
decreasing a common-mode voltage at the first terminal and the second terminal by providing current to, or drawing current from, the first terminal and the second terminal at least partially responsive to the bias signal.

22. The method of claim 21, comprising:
protecting a transistor of a current mirror used to provide the current, or draw the current, by preventing a voltage at a source or drain of the transistor from exceeding a safe-operational threshold.

23. The method of claim 21, comprising:
protecting an operational amplifier used to generate the bias signal by preventing the feedback signal from exceeding a threshold.
